(19) United States
(12) Patent Application Publication
(10) Pub. No.: US 2024/0389399 A1
(43) Pub. Date: Nov. 21, 2024

(54) DISPLAY DEVICE

(71) Applicant: Japan Display Inc., Tokyo (JP)

(72) Inventors: Hideyuki TAKAHASHI, Tokyo (JP); Hiroyuki KIMURA, Tokyo (JP); Hiroshi TABATAKE, Tokyo (JP)

(73) Assignee: Japan Display Inc., Tokyo (JP)

(21) Appl. No.: 18/640,000

(22) Filed: Apr. 19, 2024

(30) Foreign Application Priority Data
May 19, 2023 (JP) 2023-082994

(51) Int. Cl. H10K 59/122; H10K 59/35

(52) U.S. Cl. CPC H10K 59/122; H10K 59/353

(57) ABSTRACT

According to one embodiment, a display device includes a display area which includes subpixels, and a partition which includes a conductive lower portion and an upper portion which protrudes from a side surface of the lower portion and surrounds each of the subpixels. Each of the subpixels includes a lower electrode, an organic layer which covers the lower electrode, and an upper electrode which covers the organic layer and is in contact with the lower portion of the partition. The display area has a transmissive area located between the lower electrodes of the adjacent two subpixels. Further, the partition surrounds the transmissive area.

### CROSS-REFERENCE TO RELATED APPLICATION

This application is based upon and claims the benefit of priority from Japanese Patent Application No. 2023-082994, filed May 19, 2023, the entire contents of which are incorporated herein by reference.

### FIELD

Embodiments described herein relate generally to a display device.

### BACKGROUND

Recently, display devices to which an organic light emitting diode (OLED) is applied as a display element have been put into practical use. This display element comprises a lower electrode, an organic layer which covers the lower electrode, and an upper electrode which covers the organic layer. Common voltage is applied to the upper electrode of each display element through lines provided in a display area.

Translucency is required in some display devices. However, if the above lines are formed of a material having light-shielding properties, such as metal, the translucency of the display device could be considerably decreased.

### BRIEF DESCRIPTION OF THE DRAWINGS

FIG. 1 is a diagram showing a configuration example of a display device according to a first embodiment.

FIG. 2 is a schematic plan view of a display area according to the first embodiment.

FIG. 3 is a schematic plan view in which the area surrounded by the chained frame III of FIG. 2 is enlarged.

FIG. 4 is a schematic cross-sectional view of the display device along the IV-IV line of FIG. 3.

FIG. 5 is a schematic cross-sectional view of the display device along the V-V line of FIG. 3.

FIG. 6 is a schematic plan view of the display area of a display device according to a second embodiment.

FIG. 7 is a schematic plan view of the display area of a display device according to a third embodiment.

FIG. 8 is a schematic plan view in which the area surrounded by the chained frame VIII of FIG. 7 is enlarged.

### DETAILED DESCRIPTION

In general, according to one embodiment, a display device comprises a display area which includes a plurality of subpixels, and a partition which includes a conductive lower portion and an upper portion which protrudes from a side surface of the lower portion and surrounds each of the subpixels. Each of the subpixels includes a lower electrode, an organic layer which covers the lower electrode and emits light based on application of voltage, and an upper electrode which covers the organic layer and is in contact with the lower portion of the partition. The display area has a transmissive area located between the lower electrodes of the adjacent two subpixels. Further, the partition surrounds the transmissive area.

The embodiment can provide a display device with excellent translucency.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as an X-direction. A direction parallel to the Y-axis is referred to as a Y-direction. A direction parallel to the Z-axis is referred to as a Z-direction. The Z-direction is a normal direction relative to a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

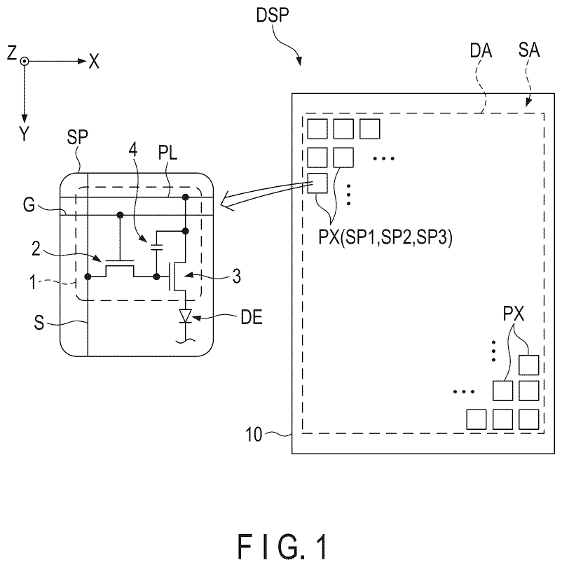

FIG. 1 is a diagram showing a configuration example of a display device DSP according to a first embodiment. The display device DSP comprises an insulating substrate 10. The substrate 10 has a display area DA which displays an image, and a surrounding area SA around the display area DA. The substrate 10 may be glass or a resinous film having flexibility.

In this embodiment, the substrate 10 is rectangular as seen in plan view. It should be noted that the shape of the substrate 10 in plan view is not limited to a rectangle and may be another shape such as a square, a circle or an oval.

The display area DA comprises a plurality of pixels PX arrayed in matrix in an X-direction and a Y-direction. Each pixel PX includes a plurality of subpixels SP which display different colors. This embodiment assumes a case where each pixel PX includes a blue subpixel SP1, a green subpixel SP2 and a red subpixel SP3. Here, subpixels SP1, SP2 and SP3 are examples of first, second and third subpixels. Further, blue, green and red are examples of first, second and third colors. Each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

In the display area DA, a plurality of scanning lines G which supply a scanning signal to the pixel circuit 1 of each subpixel SP, a plurality of signal lines S which supply a video signal to the pixel circuit 1 of each subpixel SP and a plurality of power lines PL are provided. In the example of FIG. 1, the scanning lines G and the power lines PL extend in the X-direction, and the signal lines S extend in the Y-direction.

The gate electrode of the pixel switch 2 is connected to the scanning line G. One of the source electrode and drain electrode of the pixel switch 2 is connected to the signal line S. The other one is connected to the gate electrode of the drive transistor 3 and the capacitor 4. In the drive transistor 3, one of the source electrode and the drain electrode is connected to the power line PL and the capacitor 4, and the other one is connected to the display element DE.

It should be noted that the configuration of the pixel circuit 1 is not limited to the example shown in the figure. For example, the pixel circuit 1 may comprise more thin-film transistors and capacitors.

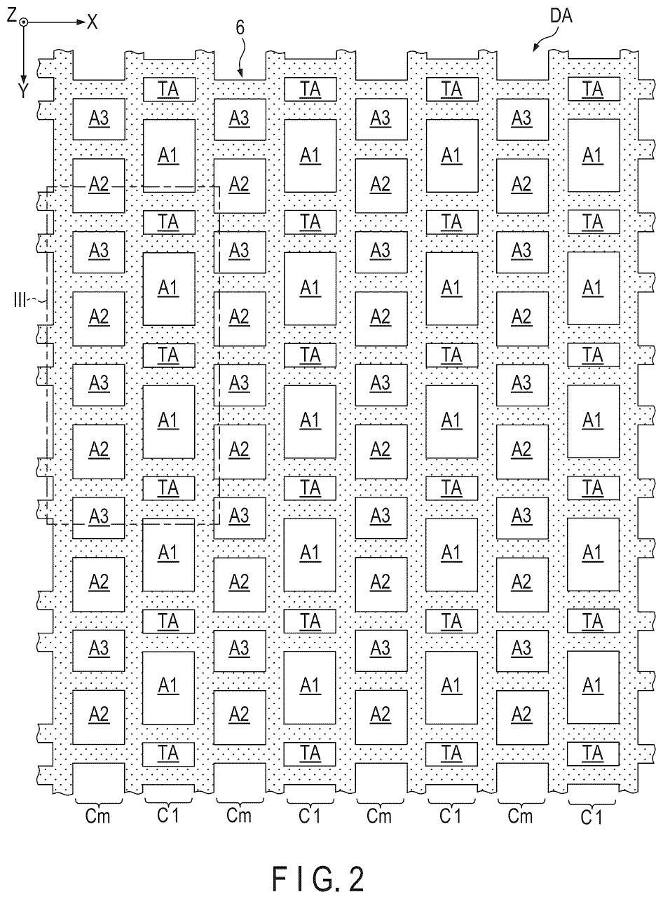

FIG. 2 is a schematic plan view of the display area DA according to the embodiment. A conductive partition 6 is provided in the display area DA. The partition 6 functions as lines which apply common voltage to the display elements DE.

The partition 6 has portions extending in the X-direction and portions extending in the Y-direction and has a grating shape as a whole. The display area DA has first areas A1, second areas A2, third areas A3 and transmissive areas TA. Each of these areas is surrounded by the partition 6.

In the example of FIG. 2, columns C1 each of which includes a plurality of first areas A1 and a plurality of transmissive areas TA and columns Cm each of which includes a plurality of second areas A2 and a plurality of third areas A3 are formed in the display area DA. The columns C1 and Cm are alternately arranged in the X-direction. In each column C1, the first areas A1 and the transmissive areas TA are alternately arranged in the Y-direction. In each column Cm, the second and third areas A2 and A3 are alternately arranged in the Y-direction.

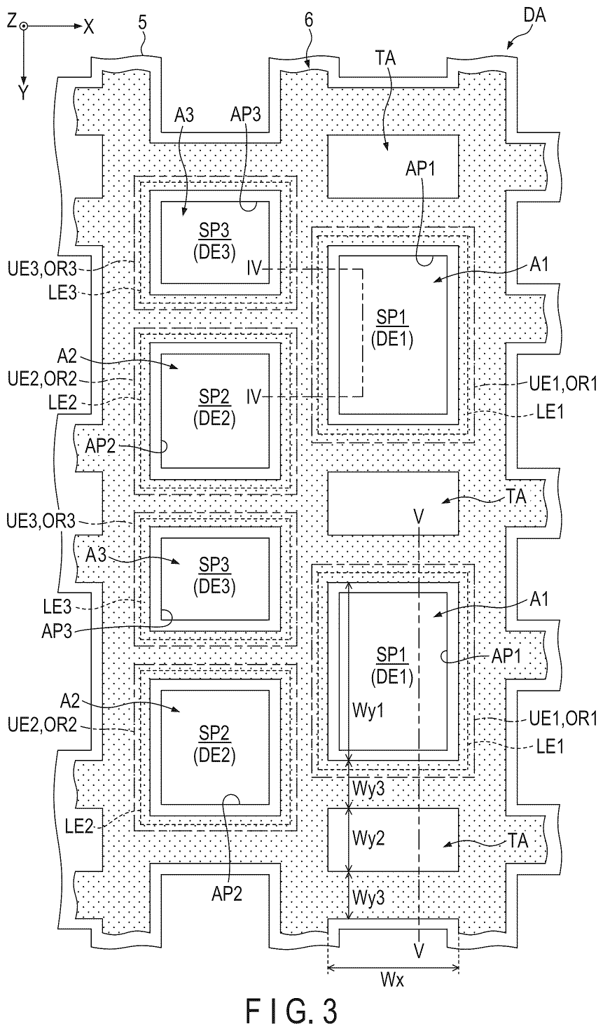

FIG. 3 is a schematic plan view in which the area surrounded by the chained frame III of FIG. 2 is enlarged. In this embodiment, subpixel SP1 is provided in each first area A1. Subpixel SP2 is provided in each second area A2. Subpixel SP3 is provided in each third area A3.

A rib 5 is provided in the display area DA. The partition 6 overlaps the rib 5 as a whole. The rib 5 has pixel apertures AP1, AP2 and AP3 in subpixels SP1, SP2 and SP3, respectively. No aperture is provided in the rib 5 in the transmissive areas TA. In other words, the transmissive areas TA overlap the rib 5 as a whole.

In the example of FIG. 3, the pixel aperture AP1 is larger than the pixel aperture AP2. The pixel aperture AP2 is larger than the pixel aperture AP3. Thus, among subpixels SP1, SP2 and SP3, the aperture ratio of subpixel SP1 is the greatest, and the aperture ratio of subpixel SP3 is the least.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3. The end portions of the lower electrodes LE1, LE2 and LE3, the upper electrodes UE1, UE2 and UE3 and the organic layers OR1, OR2 and OR3 overlap the rib 5 and the partition 6 as a whole.

Of the lower electrode LE1, the upper electrode UE1 and the organic layer OR1, the portions which overlap the pixel aperture API constitute the display element DE1 of subpixel SP1. Of the lower electrode LE2, the upper electrode UE2 and the organic layer OR2, the portions which overlap the pixel aperture AP2 constitute the display element DE2 of subpixel SP2. Of the lower electrode LE3, the upper electrode UE3 and the organic layer OR3, the portions which overlap the pixel aperture AP3 constitute the display element DE3 of subpixel SP3. Each of the display elements DE1, DE2 and DE3 may further include a cap layer as described later. The rib 5 and the partition 6 surround each of these display elements DE1, DE2 and DE3.

Each transmissive area TA is located between the lower electrodes LEI of two subpixels SP1 which are adjacent to each other in the Y-direction. The transmissive areas TA do not overlap any of the lower electrodes LE1, LE2 and LE3 or the partition 6. In addition, in the example of FIG. 3, the transmissive areas TA do not overlap the upper electrode UE1, UE2 or UE3 or the organic layer OR1, OR2 or OR3.

In the example of FIG. 3, each first area A1 is larger than each second area A2, and each second area A2 is larger than each third area A3. For example, each transmissive area TA is less than each of the areas A1, A2 and A3. However, each transmissive area TA may be larger than one of the areas A1, A2 and A3.

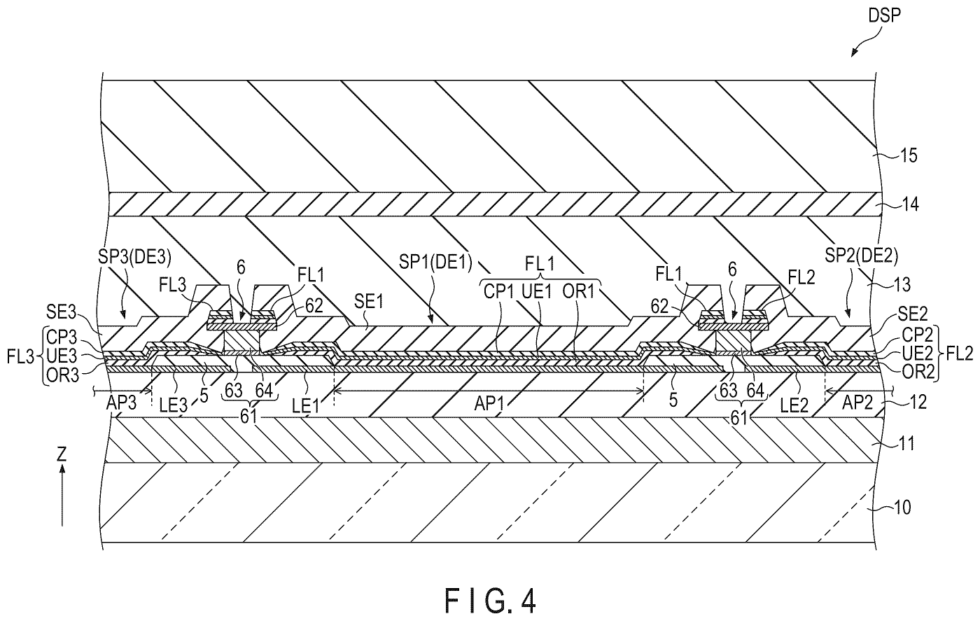

FIG. 4 is a schematic cross-sectional view of the display device DSP along the IV-IV line of FIG. 3. A circuit layer 11 is provided on the substrate 10 described above. The circuit layer 11 includes various circuits and lines such as the pixel circuits 1, scanning lines G, signal lines S and power lines PL shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2 and LE3 are provided on the organic insulating layer 12. The rib 5 is provided on the organic insulating layer 12 and the lower electrodes LE1, LE2 and LE3. The end portions of the lower electrodes LE1, LE2 and LE3 are covered with the rib 5. Although not shown in the section of FIG. 4, the lower electrodes LE1, LE2 and LE3 are connected to the respective pixel circuits 1 of the circuit layer 11 through respective contact holes provided in the organic insulating layer 12.

The partition 6 includes a conductive lower portion 61 provided on the rib 5 and an upper portion 62 provided on the lower portion 61. The upper portion 62 has a width greater than that of the lower portion 61. By this configuration, the both end portions of the upper portion 62 protrude relative to the side surfaces of the lower portion 61. This shape of the partition 6 is called an overhang shape.

In the example of FIG. 4, the lower portion 61 has a bottom portion 63 provided on the rib 5, and a stem portion 64 provided on the bottom portion 63. For example, the bottom portion 63 is formed so as to be thinner than the stem portion 64. However, the configuration is not limited to this example. In the example of FIG. 4, the side surfaces of the bottom portion 63 and the stem portion 64 are aligned with each other. However, the both end portions of the bottom portion 63 may protrude from the side surfaces of the stem portion 64.

The organic layer ORI covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2 and UE3 are in contact with the side surfaces of the lower portions 61 of the partition 6.

The display element DE1 includes a cap layer CP1 provided on the upper electrode UE1. The display element DE2 includes a cap layer CP2 provided on the upper electrode UE2. The display element DE3 includes a cap layer CP3 provided on the upper electrode UE3. The cap layers CP1, CP2 and CP3 function as optical adjustment layers which improve the extraction efficiency of the light emitted from the organic layers OR1, OR2 and OR3, respectively.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

The stacked film FL1 is partly located on the upper portion 62. This portion is spaced apart from, of the stacked film FL1, the portion located under the partition 6 (in other words, the portion which constitutes the display element DE1). Similarly, the stacked film FL2 is partly located on the upper portion 62. This portion is spaced apart from, of the stacked film FL2, the portion located under the partition 6 (in other words, the portion which constitutes the display element DE2). Further, the stacked film FL3 is partly located on the upper portion 62. This portion is spaced apart from, of the stacked film FL3, the portion located under the partition 6 (in other words, the portion which constitutes the display element DE3).

Sealing layers SE1, SE2 and SE3 are provided in subpixels SP1, SP2 and SP3, respectively. The sealing layer SE1 continuously covers the stacked film FL1 and the partition 6 around subpixel SP1. The sealing layer SE2 continuously covers the stacked film FL2 and the partition 6 around subpixel SP2. The sealing layer SE3 continuously covers the stacked film FL3 and the partition 6 around subpixel SP3.

In the example of FIG. 4, the stacked film FL1 and sealing layer SE1 located on the partition 6 between subpixels SP1 and SP2 are spaced apart from the stacked film FL2 and sealing layer SE2 located on this partition 6. The stacked film FL1 and sealing layer SE1 located on the partition 6 between subpixels SP1 and SP3 are spaced apart from the stacked film FL3 and sealing layer SE3 located on this partition 6.

It should be noted that the partition 6 functions as lines for supplying electricity to the upper electrodes UE1, UE2 and UE3 and also functions to divide the stacked films FL1, FL2 and FL3 which are formed by vapor deposition when the display device DSP is manufactured. By dividing the stacked films FL1, FL2 and FL3 in this manner, the display elements DE1, DE2 and DE3 which are individually sealed by the sealing layers SE1, SE2 and SE3 can be obtained.

The sealing layers SE1, SE2 and SE3 are covered with a resin layer 13. The resin layer 13 is covered with a sealing layer 14. The sealing layer 14 is covered with a resin layer 15. The resin layers 13 and 15 and the sealing layer 14 are continuously provided in at least the entire display area DA and partly extend in the surrounding area SA as well.

A cover member such as a polarizer, a touch panel, a protective film or a cover glass may be further provided above the resin layer 15. This cover member may be attached to the resin layer 15 via, for example, an adhesive layer such as an optical clear adhesive (OCA).

The organic insulating layer 12 is formed of an organic insulating material such as polyimide. Each of the rib 5 and the sealing layers 14, SE1, SE2 and SE3 is formed of an inorganic insulating material such as silicon nitride (SiNx), silicon oxide (SiOx), silicon oxynitride (SiON) or aluminum oxide (A1₂O₃). For example, the rib 5 is formed of silicon oxynitride, and each of the sealing layers 14, SE1, SE2 and SE3 is formed of silicon nitride. Each of the resin layers 13 and 15 is formed of, for example, a resinous material (organic insulating material) such as epoxy resin or acrylic resin.

Each of the lower electrodes LE1, LE2 and LE3 has a reflective layer formed of, for example, silver (Ag), and a pair of conductive oxide layers covering the upper and lower surfaces of the reflective layer. Each of the conductive oxide layers may be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

For example, each of the organic layers OR1, OR2 and OR3 comprises a multilayer structure consisting of a hole injection layer, a hole transport layer, an electron blocking layer, a light emitting layer, a hole blocking layer, an electron transport layer and an electron injection layer. Each of the organic layers OR1, OR2 and OR3 may comprise a tandem structure including a plurality of light emitting layers.

Each of the cap layers CP1, CP2 and CP3 comprises, for example, a multilayer structure in which a plurality of transparent thin films are stacked. The thin films may include a thin film formed of an inorganic material and a thin film formed of an organic material. These thin films have refractive indices different from each other. For example, the refractive indices of these thin films are different from the refractive indices of the upper electrodes UE1, UE2 and UE3 and the refractive indices of the sealing layers SE1, SE2 and SE3. It should be noted that at least one of the cap layers CP1, CP2 and CP3 may be omitted.

Each of the bottom portion 63 and stem portion 64 of the partition 6 is formed of a metal material. For the metal material of the bottom portion 63, for example, molybdenum (Mo), titanium nitride (TiN), a molybdenum-tungsten alloy (MoW) or a molybdenum-niobium alloy (MoNb) can be used. For the metal material of the stem portion 64, for example, aluminum, an aluminum-neodymium alloy (AlNd), an aluminum-yttrium alloy (AlY) or an aluminum-silicon alloy (AlSi) can be used. It should be noted that the stem portion 64 may be formed of an insulating material.

For example, the upper portion 62 of the partition 6 comprises a multilayer structure consisting of a lower layer formed of a metal material and an upper layer formed of conductive oxide. For the metal material forming the lower layer, for example, titanium, titanium nitride, molybdenum, tungsten, a molybdenum-tungsten alloy or a molybdenum-niobium alloy can be used. For the conductive oxide forming the upper layer, for example, ITO or IZO can be used. It should be noted that the upper portion 62 may comprise a single-layer structure of a metal material. The upper portion 62 may further include a layer formed of an insulating material.

Common voltage is applied to the partition 6. This common voltage is applied to each of the upper electrodes UE1, UE2 and UE3 which are in contact with the side surfaces of the lower portions 61. Pixel voltage is applied to the lower electrodes LE1, LE2 and LE3 through the pixel circuits 1 provided in subpixels SP1, SP2 and SP3, respectively, based on the video signals of the signal lines S.

The organic layers OR1, OR2 and OR3 emit light based on the application of voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2 and OR3 may emit light exhibiting the same color (for example, white). In this case, the display device DSP may comprise color filters which convert the light emitted from the light emitting layers into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers.

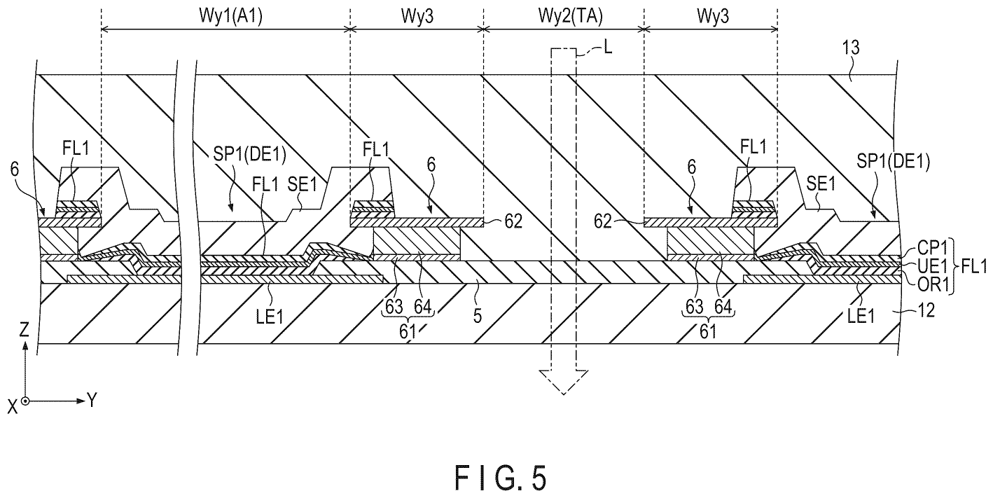

FIG. 5 is a schematic cross-sectional view of the display device DSP along the V-V line of FIG. 3. In this figure, the illustrations of the substrate 10, the circuit layer 11, the sealing layer 14 and the resin layer 15 are omitted.

As described above, no aperture is provided in the rib 5 in the transmissive area TA. Neither the stacked film FL1 nor the sealing layer SE1 is provided in the transmissive area TA. The inner space of the partition 6 surrounding the transmissive area TA is filled with the resin layer 13. In other words, the resin layer 13 is in contact with the rib 5 in the transmissive area TA.

As shown in FIG. 3 and FIG. 5, the first area A1 has width Wy1 in the Y-direction. The transmissive area TA has width Wy2 in the Y-direction. The partition 6 located between the first area A1 and the transmissive area TA has width Wy3 in the Y-direction. Width Wy1 corresponds to the distance between the end portions of the upper portions 62 of the partitions 6 located on the both sides of the first area A1 in the Y-direction. Width Wy2 corresponds to the distance between the end portions of the upper portions 62 of the partitions 6 located on the both sides of the transmissive area TA in the Y-direction. Width Wy3 corresponds to the width of the upper portion 62 of the partition 6 located between the first area A1 and the transmissive area TA.

In the embodiment, width Wy2 is less than width Wy1 (Wy2<Wy1). Width Wy2 is greater than width Wy3 (Wy3<Wy2). For example, width Wy2 is 10 μm, and width Wy3 is 7 μm.

In the example of FIG. 3, each first area A1 and each transmissive area TA have the same width Wx in the X-direction. Width Wx corresponds to the distance between the end portions of the upper portions 62 of the partition 6 located on the both sides of each first area A1 or each transmissive area TA in the X-direction. It should be noted that the widths of each first area A1 and each transmissive area TA in the X-direction may be different from each other.

Here, examples of the effects obtained from the embodiment are explained.

Electronic devices on which the display device DSP is mounted may comprise an optical sensor such as an illumination sensor which detects external light. When such an optical sensor is provided on the rear side of the display device DSP, translucency is required in the display device DSP.

However, each of the lower electrodes LE1, LE2 and LE3 includes the reflective layer described above. In addition, the partition 6 which is at least partly formed of a metal material has light-shielding properties. For this reason, if the lower electrodes LE1, LE2 and LE3 and the partition 6 are formed in the entire display area DA, the light which is made incident on the display surface of the display device DSP could be mostly reflected or blocked without being transmitted to the rear side.

To the contrary, in the embodiment, the transmissive areas TA shown in FIG. 3 and FIG. 5 are formed in the display area DA. Neither the lower electrodes LE1 nor the partition 6 is provided in the transmissive areas TA. Thus, external light L which enters each transmissive area TA can be transmitted to the lower side of the display device DSP without being blocked by the lower electrode LE1 or the partition 6 as shown in FIG. 5. By this configuration, the translucency of the display device DSP can be enhanced.

Further, in the embodiment, the stacked film FL1, FL2 or FL3 is not provided in the transmissive areas TA. By this configuration, the translucency of the transmissive areas TA can be further increased.

It is difficult to provide an aperture corresponding to each transmissive area TA when the partition 6 is patterned unless the size of the transmissive area TA is increased to some extent. However, if each transmissive area TA is enlarged, the aperture ratios of subpixels SP1, SP2 and SP3 could be decreased. In this regard, in this embodiment, each transmissive area TA is provided between adjacent two subpixels SP1. As described above, the aperture ratio of each subpixel SP1 is greater than the aperture ratios of subpixels SP2 and SP3. Therefore, even if the size of each subpixel SP1 needs to be reduced because of the provision of the transmissive areas TA, the aperture ratios of subpixels SP1, SP2 and SP3 can be easily balanced, and the effect caused to the display quality can be reduced.

The configuration disclosed in this embodiment could be modified in various ways. The second and third embodiments described below disclose other examples of configurations which could be applied to the partition 6. The configurations and effects which are not particularly referred to in these embodiments are the same as the first embodiment.

### Second Embodiment

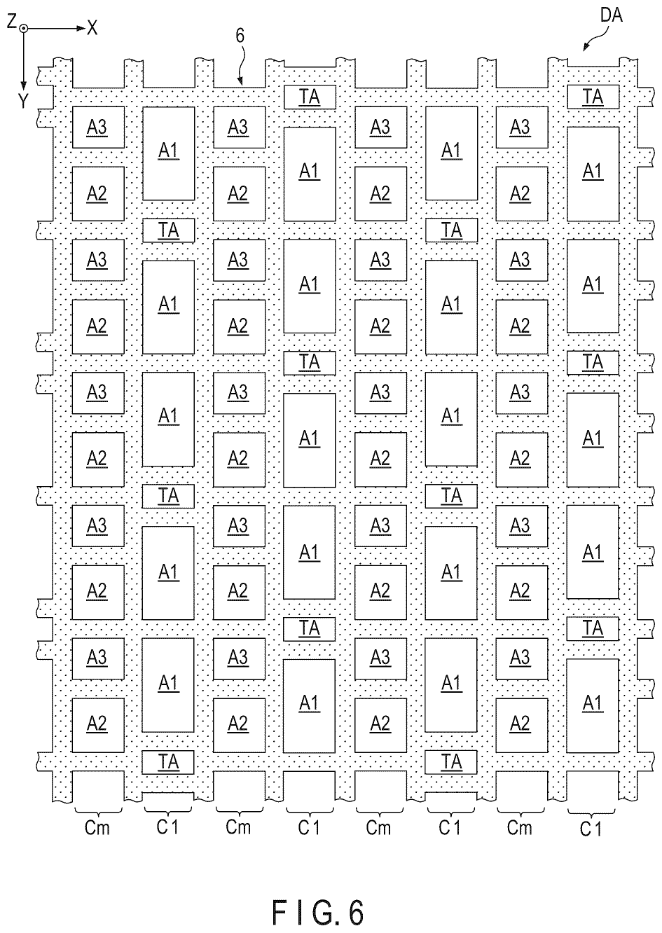

FIG. 6 is a schematic plan view of the display area DA of a display device DSP according to a second embodiment. In the example of FIG. 6, the number of transmissive areas TA is reduced compared to the example of FIG. 2.

Specifically, the transmissive areas TA are provided in the proportion of two first areas A1 to one transmissive area TA in each of a plurality of columns C1. From another view point, two first areas A1 (subpixels SP1) are provided between two transmissive areas TA which are adjacent to each other in a Y-direction. When the number of transmissive areas TA is reduced in this manner, as the size of each subpixel SP1 can be increased, the aperture ratio of each subpixel SP1 can be increased compared to the first embodiment.

Further, in the example of FIG. 6, the position of each transmissive area TA of a column C1 (first column) and the position of each transmissive area TA of an adjacent column C1 (second column) are misaligned with each other in the Y-direction. In this configuration, the positions of the transmissive areas TA in the display area DA are dispersed. Thus, the visual quality effected by reflection of a partition 6 which surrounds the transmissive areas TA can be made uniform in the display area DA.

It should be noted that the layout form of the transmissive areas TA is not limited to the examples shown in the first or second embodiment. For example, the transmissive areas TA may be provided in the proportion of three or more subpixels SP1 to one transmissive area TA. Further, each transmissive area TA may be provided between subpixels SP2 and SP3.

### Third Embodiment

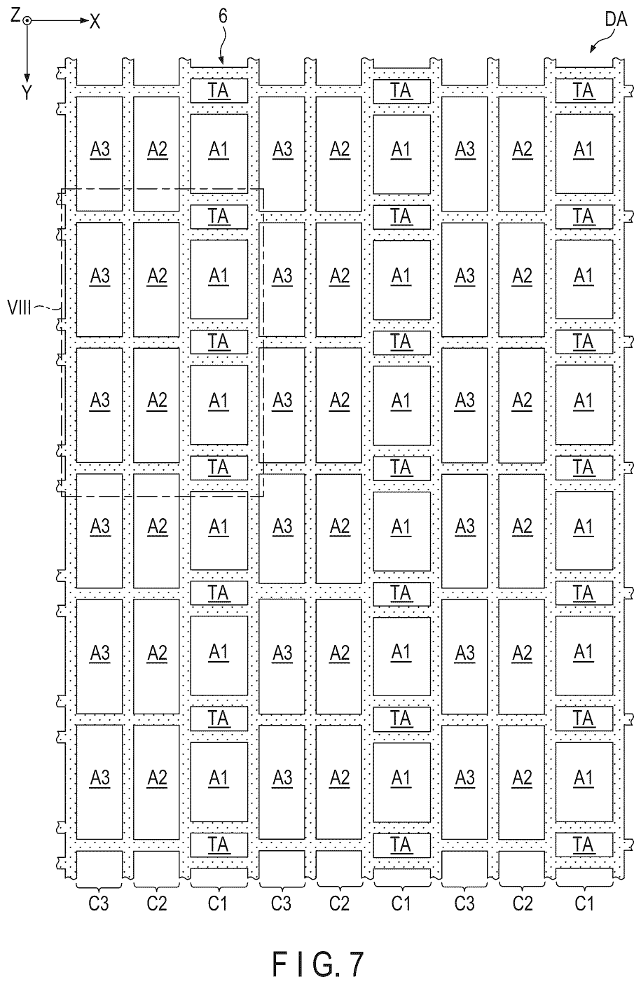

FIG. 7 is a schematic plan view of the display area DA of a display device DSP according to a third embodiment. In a manner similar to that of each of the above embodiments, the display area DA has first areas A1, second areas A2, third areas A3 and transmissive areas TA.

A plurality of columns C1, a plurality of columns C2 and a plurality of columns C3 are formed in the display area DA shown in FIG. 7. The columns C1, C2 and C3 are alternately arranged in an X-direction. Each column C1 includes a plurality of first areas A1 and a plurality of transmissive areas TA alternately arranged in a Y-direction. Each column C2 includes a plurality of second areas A2 arranged in the Y-direction. Each column C3 includes a plurality of third areas A3 arranged in the Y-direction.

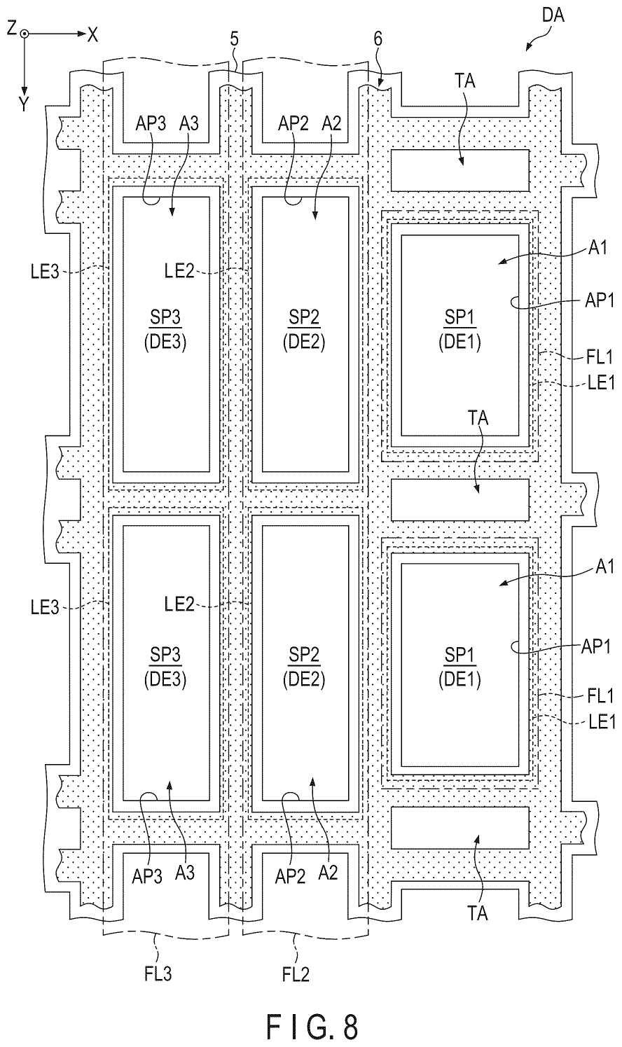

FIG. 8 is a schematic plan view in which the area surrounded by the chained frame VIII of FIG. 7 is enlarged. In a manner similar to that of the first embodiment, subpixel SP1 is provided in each first area A1. Subpixel SP2 is provided in each second area A2. Subpixel SP3 is provided in each third area A3.

In the example of FIG. 8, the width of each pixel aperture AP1 in the X-direction is greater than each of the width of each pixel aperture AP2 in the X-direction and the width of each pixel aperture AP3 in the X-direction. To the contrary, the width of each pixel aperture API in the Y-direction is less than each of the width of each pixel aperture AP2 in the Y-direction and the width of each pixel aperture AP3 in the Y-direction. For example, the aperture ratio of each subpixel SP1 is greater than that of each of subpixels SP2 and SP3. The relationships of the sizes of the areas A1, A2 and A3 are similar to those of the pixel apertures AP1, AP2 and AP3.

In a manner similar to that of the first embodiment, each transmissive area TA is located between the lower electrodes LEI of two subpixels SP1 which are adjacent to each other in the Y-direction. In the example of FIG. 8, each transmissive area TA is smaller than each of the areas A1, A2 and A3. However, each transmissive area TA may be larger than one of the areas A1, A2 and A3.

In the example of FIG. 8, the stacked films FL1 (the organic layers OR1, the upper electrodes UE1 and the cap layers CP1) of two subpixels SP1 which are adjacent to each other via the transmissive area TA are spaced apart from each other. To the contrary, a stacked film FL2 (an organic layer OR2, an upper electrode UE2 and a cap layer CP2) extends over a plurality of subpixels SP2 arranged in the Y-direction. Similarly, a stacked film FL3 (an organic layer OR3, an upper electrode UE3 and a cap layer CP3) extends over a plurality of subpixels SP3 arranged in the Y-direction. It should be noted that these stacked films FL2 and FL3 are divided by a partition 6 having an overhang shape.

In the configuration of this embodiment, effects similar to those of the first embodiment can be obtained by providing the transmissive areas TA. In a manner similar to that of the second embodiment, the transmissive areas TA may be provided in the proportion of a plurality of first areas A1 to one transmissive area TA. In this case, the positions of the transmissive areas TA of two columns C1 (first and second columns) may be misaligned with each other in the Y-direction.

Moreover, in the configuration of this embodiment, each transmissive area TA may be provided between two subpixels SP2 which are adjacent to each other in the Y-direction or between two subpixels SP3 which are adjacent to each other in the Y-direction.

The shape of the partition 6 and the layout of subpixels SP1, SP2 and SP3 in the display area DA could be modified in various ways different from the first to third embodiments described above.

All of the display devices that can be implemented by a person of ordinary skill in the art through arbitrary design changes to the display device described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or adding or omitting a step or changing the condition of a step, all of the modifications fall within the scope of the present invention as long as they are in keeping with the spirit of the invention.

Further, other effects which may be obtained from each embodiment and are self-explanatory from the descriptions of the specification or can be arbitrarily conceived by a person of ordinary skill in the art are considered as the effects of the present invention as a matter of course.

What is claimed is:

1. A display device comprising:
a display area which includes a plurality of subpixels; and
a partition which includes a conductive lower portion and an upper portion which protrudes from a side surface of the lower portion, and surrounds each of the subpixels, wherein
each of the subpixels includes:
a lower electrode;
an organic layer which covers the lower electrode and emits light based on application of voltage; and
an upper electrode which covers the organic layer and is in contact with the lower portion of the partition,
the display area has a transmissive area located between the lower electrodes of the adjacent two subpixels, and
the partition surrounds the transmissive area.

2. The display device of claim 1, wherein
the subpixels include a plurality of first subpixels which display a first color, and
the transmissive area is located between the lower electrodes of the adjacent two first subpixels.

3. The display device of claim 2, wherein
the subpixels further include a plurality of second subpixels which display a second color different from the first color, and a plurality of third subpixels which display a third color different from the first color and the second color, and
an aperture ratio of each of the first subpixels is greater than an aperture ratio of each of the second subpixels and an aperture ratio of each of the third subpixels.

4. The display device of claim 3, wherein
the first color is blue, the second color is green, and the third color is red.

5. The display device of claim 2, wherein
the display area has first and second columns each of which includes the first subpixels and the transmissive area,
the first column and the second column are arranged in a first direction,
the first subpixels are arranged in a second direction intersecting with the first direction in each of the first and second columns, and
a position of the transmissive area of the first column and a position of the transmissive area of the second column are misaligned with each other in the second direction.

6. The display device of claim 2, wherein
the display area has a column which includes the first subpixels and the transmissive areas, and
the first subpixels and the transmissive areas are alternately arranged in the column.

7. The display device of claim 2, wherein
the display area has a column which includes the first subpixels and the transmissive areas, and
the first subpixels are provided between the adjacent two transmissive areas.

8. The display device of claim 2, wherein
each of the first subpixels is provided in a first area surrounded by the partition, and
the transmissive area is smaller than the first area.

9. The display device of claim 8, wherein
a width of the transmissive area in a first direction is equal to a width of the first area in the first direction, and
a width of the transmissive area in a second direction intersecting with the first direction is less than a width of the first area in the second direction.

10. The display device of claim 9, wherein
the width of the transmissive area in the second direction is greater than a width of the partition located between the first area and the transmissive area in the second direction.

11. The display device of claim 1, further comprising a rib having a pixel aperture overlapping the lower electrode in each of the subpixels, wherein
the partition is provided on the rib, and
the transmissive area overlaps the rib.

12. The display device of claim 1, wherein
neither the organic layer nor the upper electrode is provided in the transmissive area.

13. The display device of claim 12, further comprising a sealing layer formed of an inorganic insulating material which covers a stacked film including the organic layer and the upper electrode, wherein
the sealing layer is not provided in the transmissive area.

14. The display device of claim 13, further comprising a resin layer which covers the sealing layer, wherein
an inner space of the partition which surrounds the transmissive area is filled with the resin layer.

15. The display device of claim 1, wherein
the subpixels include a first subpixel which displays a first color, a second subpixel which displays a second color different from the first color, and a third subpixel which displays a third color different from the first color and the second color,
the first subpixel is provided in a first area surrounded by the partition,
the second subpixel is provided in a second area surrounded by the partition,
the third subpixel is provided in a third area surrounded by the partition,
a width of the first area in a first direction is greater than each of a width of the second area in the first direction and a width of the third area in the first direction, and
the transmissive area and the first area are arranged in a second direction intersecting with the first direction.

16. The display device of claim 15, wherein
a width of the first area in the second direction is less than each of a width of the second area in the second direction and a width of the third area in the second direction.

17. The display device of claim 16, wherein
a width of the transmissive area in the first direction is equal to the width of the first area in the first direction, and
a width of the transmissive area in the second direction is less than the width of the first area in the second direction.
